(19) United States
(12) Patent Application Publication
(10) Pub. No.: US 2026/0003279 A1
(43) Pub. Date: Jan. 1, 2026

(54) PHOTORESIST COMPOSITION INCLUDING ORGANOMETALLIC OXIDE CLUSTER HAVING HETEROGENEOUS INORGANIC ELEMENTS AND METHOD OF MANUFACTURING INTEGRATED CIRCUIT DEVICE BY USING THE PHOTORESIST COMPOSITION

(71) Applicant: Samsung Electronics Co., Ltd., Suwon-si (KR)

(72) Inventors: Ahram SUH, Suwon-si (KR); Bongjin MOON, Seoul-si (KR); Yool KANG, Suwon-si (KR); Woojung KIM, Seoul-si (KR); Taeyoon PARK, Seoul-si (KR); Hanbee KIM, Suwon-si (KR); Jaeseung ROH, Suwon-si (KR); Sangwon EOM, Suwon-si (KR); Kwanheum LEE, Suwon-si (KR)

(73) Assignees: Samsung Electronics Co., Ltd., Suwon-si (KR); SOGANG UNIVERSITY RESEARCH FOUNDATION, Seoul (KR)

(21) Appl. No.: 19/009,226

(22) Filed: Jan. 3, 2025

(30) Foreign Application Priority Data
Jun. 27, 2024 (KR) 10-2024-0084828

(51) Int. Cl. G03F 7/038; G03F 7/00; H01L 21/308

(52) U.S. Cl. CPC G03F 7/0388; G03F 7/70025; G03F 7/70033; H01L 21/3081

(57) ABSTRACT

A photoresist composition may include an organometallic oxide cluster and a solvent. The organometallic oxide cluster may include a first repeating unit represented by General Formula 1 and a second repeating unit represented by General Formula 2.

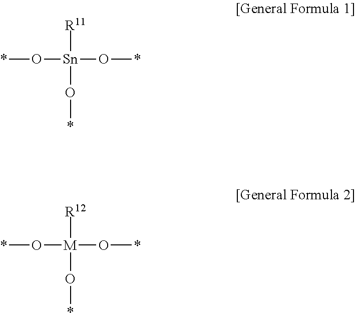

In General Formulae 1 and 2, R¹¹, R¹², and M may be the same as defined in the detailed description, and * may represent a binding site.

### CROSS-REFERENCE TO RELATED APPLICATION

This application is based on and claims priority under 35 U.S.C. § 119 to Korean Patent Application No. 10-2024-0084828, filed on Jun. 27, 2024, in the Korean Intellectual Property Office, the disclosure of which is incorporated by reference herein in its entirety.

### BACKGROUND

Inventive concepts relate to a photoresist composition and/or an integrated circuit device, and more particularly, to a photoresist composition including an organometallic oxide cluster having heterogeneous inorganic elements and/or a method of manufacturing an integrated circuit device by using the photoresist composition.

Due to the advance of electronics technology, integrated circuit devices have been rapidly down-scaled. Therefore, photolithography processes may be required to implement fine patterns. It may be necessary to develop materials capable of providing process stability, improved and/or excellent etch resistance, and/or improved and/or excellent resolution in photolithography processes for manufacturing integrated circuit devices.

### SUMMARY

Inventive concepts provide a photoresist composition, which may provide sufficient mechanical strength to secure etch selectivity in an etching process for manufacturing an integrated circuit device and/or may provide improved and/or excellent coating properties during the formation of a photoresist film, even when the size and thickness of a photoresist pattern are reduced.

Inventive concepts also provide a method of manufacturing an integrated circuit device, the method being capable of improving process stability and/or reliability by using a photoresist composition that may provide improved and/or excellent coating properties during the formation of a photoresist film and/or also may be capable of securing sufficient etch selectivity and/or mechanical strength when an etching process is performed by using a photoresist pattern despite a reduction in the size and/or thickness of the photoresist pattern obtained from the photoresist composition.

According to an embodiment of inventive concepts, a photoresist composition may include an organometallic oxide cluster and a solvent, wherein the organometallic oxide cluster may include a copolymer including a first repeating unit represented by General Formula 1 and a second repeating unit represented by General Formula 2:

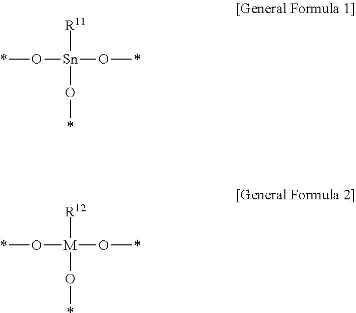

wherein, in General Formulae 1 and 2, R¹¹ and R¹² each independently may be a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R¹¹ and R¹² has a substituent, the substituent includes a hydrocarbyl group that is substituted with at least one heteroatom functional group including an oxygen atom, a nitrogen atom, a halogen element, a cyano group, a thio group, a silyl group, an ether group, a carbonyl group, an ester group, a nitro group, an amino group, or a combination thereof,
* may represent a binding site, and,
in General Formula 2,
M may be Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

According to an embodiment of inventive concepts, a photoresist composition may include an organometallic oxide cluster and a solvent, wherein the organometallic oxide cluster may include a copolymer including a first repeating unit represented by General Formula 1 and a second repeating unit represented by General Formula 2A:

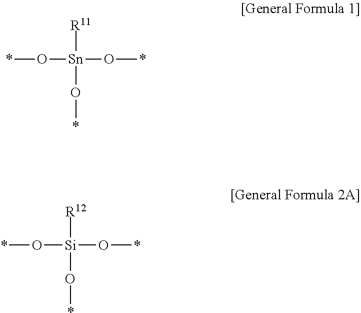

wherein, in General Formulae 1 and 2A,
R¹¹ and R¹² each independently may include a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R¹¹ and R¹² has a substituent, the substituent includes a hydrocarbyl group that is substituted with at least one heteroatom functional group including an oxygen atom, a nitrogen atom, a halogen element, a cyano group, a thio group, a silyl group, an ether group, a carbonyl group, an ester group, a nitro group, an amino group, or a combination thereof, and
* may represent a binding site.

According to an embodiment of inventive concepts, a method of manufacturing an integrated circuit device may include forming a device layer on a substrate, forming a photoresist film on the device layer by using a photoresist composition including an organometallic oxide cluster and a solvent, forming a heterogeneous inorganic network from the organometallic oxide cluster in a first region of the photoresist film by exposing the first region of the photoresist film to light, forming a photoresist pattern including the heterogeneous inorganic network by developing the photoresist film including the first region that is exposed to light, and etching the device layer by using the photoresist pattern as a mask. The first region of the photoresist film may be a portion of the photoresist film. In the forming of the photoresist film, the organometallic oxide cluster may include a copolymer including a first repeating unit represented by General Formula 1 shown above and a second repeating unit represented by General Formula 2 shown above.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing an integrated circuit device, according to embodiments;

FIGS. 2A to 2F are cross-sectional views respectively illustrating operations of a method of manufacturing an integrated circuit device, according to embodiments;

FIG. 3A is a ¹H-nuclear magnetic resonance spectroscopy (NMR) spectrum of each of a product and reactants used for the synthesis of an organometallic oxide cluster that may be included in a photoresist composition according to embodiments;

FIG. 3B is a ¹³C-NMR spectrum of each of a product and reactants used for the synthesis of an organometallic oxide cluster that may be included in a photoresist composition according to embodiments;

FIG. 4 is an electrospray ionization mass spectrometry (ESI-MS) spectrum of an organometallic oxide cluster that may be included in a photoresist composition according to embodiments;

FIG. 5 is a spectrum obtained by enlarging the peak at a mass-to-charge ratio (m/z)=1330 in the ESI-MS spectrum of FIG. 4;

FIG. 6 is a ¹H-NMR spectrum of organometallic oxide clusters that may be included in a photoresist composition according to embodiments;

FIG. 7 is a ¹H-NMR spectrum of each of a product and reactants used for the synthesis of another organometallic oxide cluster that may be included in a photoresist composition according to embodiments;

FIG. 8 is an ESI-MS spectrum of another organometallic oxide cluster that may be included in a photoresist composition according to embodiments;

FIG. 9 is a ¹H-NMR spectrum of each of a product and reactants used for the synthesis of another organometallic oxide cluster that may be included in a photoresist composition according to embodiments;

FIG. 10 is an ESI-MS spectrum of another organometallic oxide cluster that may be included in a photoresist composition according to embodiments;

FIG. 11 is a ¹H-NMR spectrum of each of a product and reactants used for the synthesis of another organometallic oxide cluster that may be included in a photoresist composition according to embodiments;

FIG. 12 is an ESI-MS spectrum of another organometallic oxide cluster that may be included in a photoresist composition according to embodiments;

FIG. 13 is a ¹H-NMR spectrum of each of a comparative product and reactants used for the synthesis of a comparative compound;

FIG. 14 is an ESI-MS spectrum of a comparative product obtained as a result of the synthesis of a comparative compound;

FIG. 15 is a ¹H-NMR spectrum of each of a comparative product and reactants used for the synthesis of another comparative compound;

FIG. 16 is an ESI-MS spectrum of another comparative product obtained as a result of the synthesis of another comparative compound; and

FIGS. 17 to 19 are each a scanning electron microscope (SEM) image of a photoresist pattern obtained from a photoresist composition according to embodiments.

### DETAILED DESCRIPTION

Hereinafter, embodiments of inventive concepts will be described in detail with reference to the accompanying drawings. Like components are denoted by like reference numerals throughout the specification, and repeated descriptions thereof are omitted.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

As used herein, the abbreviation “Bu” refers to a butyl group, the abbreviation “iBu” refers to an isobutyl group, the abbreviation “nBu” refers to a normal butyl group, the abbreviation “Ph” refers to a phenyl group, and the abbreviation “Cy” refers to a cyclohexyl group.

A photoresist composition according to embodiments may include an organometallic oxide cluster and a solvent, the organometallic oxide cluster having heterogeneous inorganic elements. The organometallic oxide cluster may include a copolymer including a first repeating unit represented by General Formula 1 and a second repeating unit represented by General Formula 2.

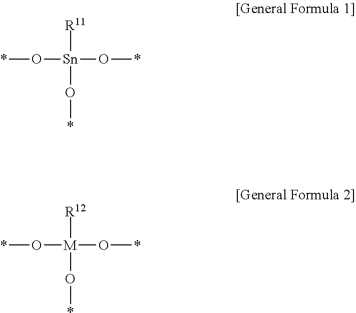

In General Formulae 1 and 2, R¹¹ and R¹² each independently may be a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group. Here, R² is a substituted or unsubstituted C1-C10 alkyl group or a substituted or unsubstituted phenyl group. Each of R¹¹ and R¹² independently may include a hydrocarbyl group that is substituted with at least one heteroatom functional group including an oxygen atom, a nitrogen atom, a halogen element, a cyano group, a thio group, a silyl group, an ether group, a carbonyl group, an ester group, a nitro group, an amino group, or a combination thereof. The halogen element may include an F atom, a Cl atom, a Br atom, or an I atom. In General Formulae 1 and 2, * represents a binding site.

In General Formula 2, M may be an inorganic element that is different from tin (Sn). In General Formula 2, M may be, but is not limited to, Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

Unless otherwise stated, the term “substituted” used herein refers to including at least one substituent, for example, a halogen element (for example, an F atom, a C1 atom, a Br atom, or an I atom), a hydroxyl group, an amino group, a thiol group, a carboxyl group, a carboxylate group, an ester group, an amide group, a nitrile group, a sulfide group, a disulfide group, a nitro group, a C1-C20 alkyl group, a C3-C20 cycloalkyl group, a C2-C20 alkenyl group, a C1-C20 alkoxy group, a C2-C20 alkenoxy group, a C2-C30 aryl group, a C6-C30 aryloxy group, a C7-C30 alkylaryl group, or a C7-C30 alkylaryloxy group.

In some embodiments, in General Formulae 1 and 2, R¹¹ and R¹² may each be a C1-C30 linear alkyl group, a C1-C30 branched alkyl group, a C3-C30 cycloalkyl group, a C6-C30 aryl group, or a C7-C30 alkylaryl group.

In some embodiments, in General Formulae 1 and 2, R¹¹ and R¹² may each be: an alkyl group, such as a methyl group, an ethyl group, a n-propyl group, an isopropyl group, a n-butyl group, an isobutyl group, or a t-butyl group; a monovalent saturated cycloaliphatic hydrocarbon group, such as a cyclopropyl group, a cyclopentyl group, a cyclohexyl group, a cyclopropylmethyl group, a 4-methylcyclohexyl group, a cyclohexylmethyl group, a norbornyl group, or an adamantyl group; an alkenyl group, such as a vinyl group, an allyl group, a propenyl group, a butenyl group, or a hexenyl group; a monovalent unsaturated cycloaliphatic hydrocarbon group, such as a cyclohexenyl group; an aryl group, such as a phenyl group or a naphthyl group; a heteroaryl group, such as a thienyl group; or an aralkyl group, such as a benzyl group, a 1-phenylethyl group, or a 2-phenylethyl group.

In some embodiments, in General Formulae 1 and 2, some of hydrogen atoms in a hydrocarbon group constituting each of R¹¹ and R¹² may be substituted with groups including a heteroatom, such as oxygen, sulfur, nitrogen, or a halogen element (for example, a fluorine atom).

In an example, R¹¹ in General Formula 1 and R¹² in General Formula 2 may respectively have different structures. In another example, R¹¹ in General Formula 1 and R¹² in General Formula 2 may have a same structure.

In some embodiments, in the organometallic oxide cluster of the photoresist composition according to embodiments, M in General Formula 2 may be Si and the second repeating unit represented by General Formula 2 may be represented by General Formula 2A.

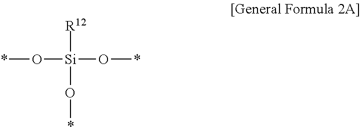

In General Formula 2A, a detailed configuration of R¹² is the same as described above. In General Formula 2A, * represents a binding site.

In some embodiments, the organometallic oxide cluster of the photoresist composition according to embodiments may include repeating units represented by General Formula 3.

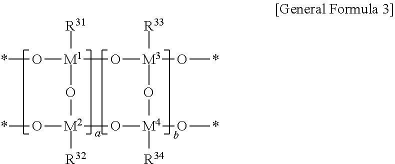

In General Formula 3, M¹, M², M³, and M⁴ are each an inorganic element, one, two, or three selected from M¹, M², M³, and M⁴ are Sn, and the others except for Sn from among M¹, M², M³, and M⁴ are Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

In General Formula 3, R³¹, R³², R³³, and R³⁴ each independently may be a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group. Here, R² may be a substituted or unsubstituted C1-C10 alkyl group or a substituted or unsubstituted phenyl group.

In General Formula 3, each of R³¹, R³², R³³, and R³⁴ may include a hydrocarbyl group that is substituted with at least one heteroatom functional group including an oxygen atom, a nitrogen atom, a halogen element, a cyano group, a thio group, a silyl group, an ether group, a carbonyl group, an ester group, a nitro group, an amino group, or a combination thereof. In General Formula 3, a/(a+b) and b/(a+b) are each 0.05 to 0.95. In General Formula 3, * represents a binding site.

In some embodiments, in General Formula 3, R³¹, R³², R³³, and R³⁴ may each be a C1-C30 linear alkyl group, a C1-C30 branched alkyl group, a C3-C30 cycloalkyl group, a C6-C30 aryl group, or a C7-C30 alkylaryl group.

For example, in General Formula 3, R³¹, R³², R³³, and R³⁴ may each be: an alkyl group, such as a methyl group, an ethyl group, a n-propyl group, an isopropyl group, a n-butyl group, an isobutyl group, or a t-butyl group; a monovalent saturated cycloaliphatic hydrocarbon group, such as a cyclopropyl group, a cyclopentyl group, a cyclohexyl group, a cyclopropylmethyl group, a 4-methylcyclohexyl group, a cyclohexylmethyl group, a norbornyl group, or an adamantyl group; an alkenyl group, such as a vinyl group, an allyl group, a propenyl group, a butenyl group, or a hexenyl group; a monovalent unsaturated cycloaliphatic hydrocarbon group, such as a cyclohexenyl group; an aryl group, such as a phenyl group or a naphthyl group; a heteroaryl group, such as a thienyl group; or an aralkyl group, such as a benzyl group, a 1-phenylethyl group, or a 2-phenylethyl group.

In some embodiments, in General Formula 3, some of hydrogen atoms in a hydrocarbon group constituting each of R³¹, R³², R³³, and R³⁴ may be substituted with groups including a heteroatom, such as oxygen, sulfur, nitrogen, or a halogen element (for example, a fluorine atom).

In some embodiments, in General Formula 3, each of R³¹, R³², R³³, and R³⁴ may include an acid group selected from a hydroxyl group, a sulfonate group, a carboxyl group, and a phosphonate group.

In some embodiments, in General Formula 3, each of R³¹, R³², R³³, and R³⁴ may include a ligand including CF₃COO—, CF₃SO₃—, CF₂CF₂SO₃—, CF₃CF₂(CF₃)₂CO—, CF₃SO₂—, a p-toluenesulfonyl group, or diethyl phosphate.

In some embodiments, in General Formula 3, each of R³¹, R³², R³³, and R³⁴ may include an aromatic ring, a heteroaromatic ring, or a combination thereof. The aromatic ring may include: a single aromatic ring, such as benzene; a heteroaryl group, such as pyridine, pyrimidine, or thiophene; a condensed aryl group, such as quinolone, isoquinoline, naphthalene, anthracene, or phenanthrene; or the like. The heteroaryl group and the condensed aryl group may each include at least one heteroatom selected from an O atom, a S atom, and a N atom.

In some embodiments, in General Formula 3, each of R³¹, R³², R³³, and R³⁴ may include at least one selected from the following structural units, where * represents a binding site, shown below:

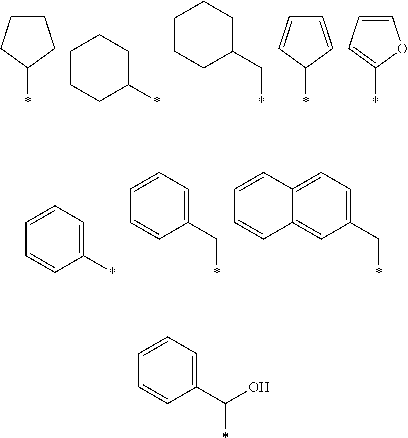

In some embodiments, in General Formula 3, M¹, M², M³, and M⁴ may each be selected from Sn and Si, and M¹, M², M³, and M⁴ may include at least one Sn atom and at least one Si atom. One, two, or three of M¹, M², M³, and M⁴ may be Sn. Others, which are not Sn, among M¹, M², M³, and M⁴ may be Si.

In some embodiments, in General Formula 3, M¹, M², M³, and M⁴ may each be Sn or Si, and in General Formula 3, the molar ratio of Sn may be equal to or greater than the molar ratio of Si. The molar ratio of Sn may be approximated as a ratio of moles Sn to moles Si and Sn in General Formula 3. The molar ratio of Si may be approximated as a ratio of moles Si to moles Si and Sn in General Formula 3.

In some embodiments, in the photoresist composition according to embodiments, the organometallic oxide cluster may include repeating units represented by General Formula 4.

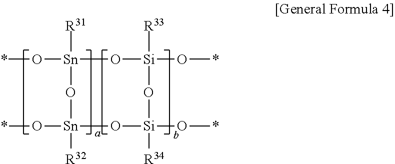

In General Formula 4, a detailed configuration of each of R³¹, R³², R³³, and R³⁴ is the same as described above. In General Formula 4, at least some selected from R³¹, R³², R³³, and R³⁴ may have a same structure. For example, in General Formula 4, R³¹ and R³² may have a same structure, and R³³ and R³⁴ may have a same structure. Here, the structure constituting each of R³¹ and R³² may be the same as or different from the structure constituting each of R³³ and R³⁴. In General Formula 4, a/(a+b) and b/(a+b) are each 0.05 to 0.95, and * represents a binding site.

In some embodiments, in the photoresist composition according to embodiments, the organometallic oxide cluster may include repeating units represented by General Formula 5.

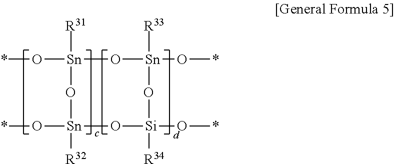

In General Formula 5, a detailed configuration of each of R³¹, R³², R³³, and R³⁴ is the same as described above. In General Formula 5, at least some selected from R³¹, R³², R³³, and R³⁴ may have a same structure. For example, in General Formula 5, R³¹, R³², and R³³ may have a same structure. R³⁴ may have a structure that is the same as or different from the structure of each of R³¹, R³², and R³³. In General Formula 5, c/(c+d) and d/(c+d) are each 0.05 to 0.95, and * represents a binding site.

In the photoresist composition according to embodiments, the solvent may include an organic solvent. The organic solvent may include, but is not limited to, at least one of ethers, alcohols, glycol ethers, aromatic hydrocarbon compounds, ketones, and esters. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or a combination thereof.

In the photoresist composition according to embodiments, the solvent may be present in the balance amount except for the organometallic oxide cluster. In some embodiments, the solvent may be present in an amount of about 0.1 wt % to about 99.8 wt % based on the total weight of the photoresist composition, but inventive concepts is not limited thereto.

In some embodiments, the photoresist composition according to embodiments may further include at least one selected from a leveling agent, a surfactant, a dispersant, a moisture absorbent, and a coupling agent.

The leveling agent is for improving coating flatness when the photoresist composition is coated on a substrate, and a commercially available leveling agent publicly known in the art may be used.

The surfactant may improve the coating uniformity and/or wettability of the photoresist composition. In some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt % to about 3 wt % based on the total weight of the photoresist composition.

The dispersant may cause the respective components constituting the photoresist composition to be uniformly dispersed in the photoresist composition. In some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt % based on the total weight of the photoresist composition.

The moisture absorbent may limit and/or prevent adverse effects due to water in the photoresist composition. In some embodiments, the moisture absorbent may include, but is not limited to, polyoxyethylene nonylphenol ether, polyethylene glycol, polypropylene glycol, polyacrylamide, or a combination thereof. When the photoresist composition includes the moisture absorbent, the moisture absorbent may be present in an amount of about 0.001 wt % to about 10 wt % based on the total weight of the photoresist composition.

The coupling agent may improve adhesion to a lower film when the photoresist composition is coated on the lower film. In some embodiments, the coupling agent may include a silane coupling agent. The silane coupling agent may include, but is not limited to, vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt % based on the total weight of the photoresist composition.

The photoresist composition according to embodiments includes an organometallic oxide cluster having heterogeneous inorganic elements. The organometallic oxide cluster includes a first repeating unit including a first inorganic element and a second repeating unit including a second inorganic element that is different from the first inorganic element. When the first inorganic element is tin (Sn), the second inorganic element may include a material capable of compensating for the relatively low mechanical strength and insufficient coating properties of tin (Sn), for example, silicon (Si). In addition, when the first inorganic element includes a material that is harmful to the human body, the second inorganic element may include a material that is less harmful to the human body than the first inorganic element. Therefore, when a photoresist pattern is formed by using the photoresist composition according to embodiments, the photoresist composition may provide sufficient mechanical strength to secure etch selectivity in an etching process for manufacturing an integrated circuit device despite a reduction in the size and/or thickness of the photoresist pattern and may provide improved and/or excellent coating properties when a photoresist film is formed by using the photoresist composition.

When an integrated circuit device is manufactured by using the photoresist composition according to embodiments, improved and/or excellent resolution and improved and/or excellent sensitivity may be provided in a photolithography process, and when a pattern required for the integrated circuit device is formed, the dimensional precision of the pattern intended to be formed may be improved by limiting and/or preventing deterioration in a critical dimension (CD) distribution of the pattern.

In addition, the photoresist composition according to inventive concepts may have a good effect in forming a pattern having a relatively high aspect ratio. For example, the photoresist composition according to inventive concepts may have a good effect for a photolithography process for forming a pattern that has a fine width selected from a range of about 5 nm to about 100 nm.

Next, a method of manufacturing an integrated circuit device by using the photoresist composition according to embodiments is described by taking a specific example.

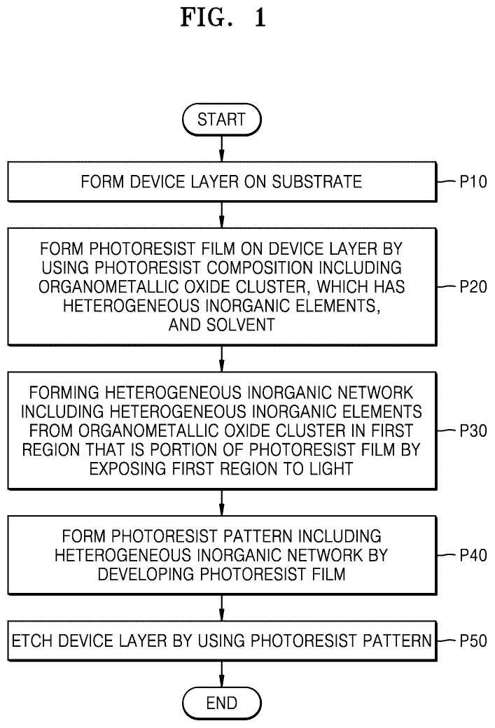

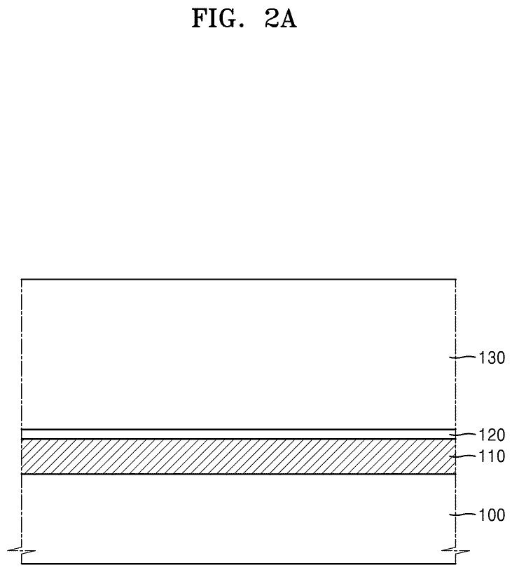

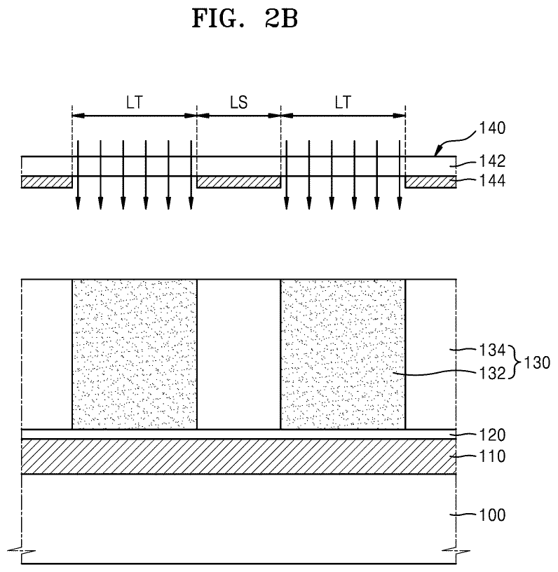

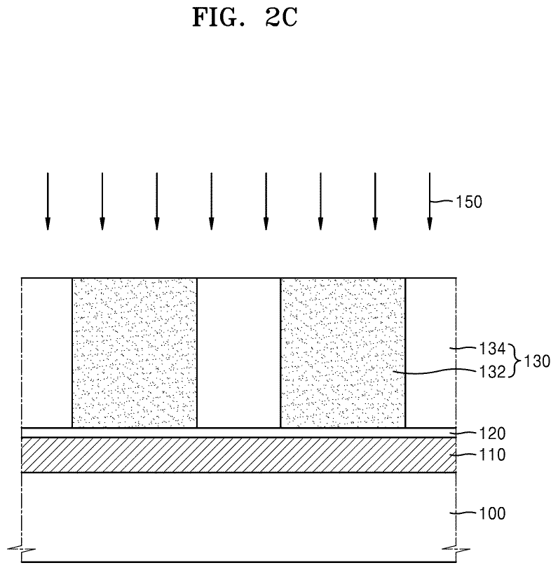

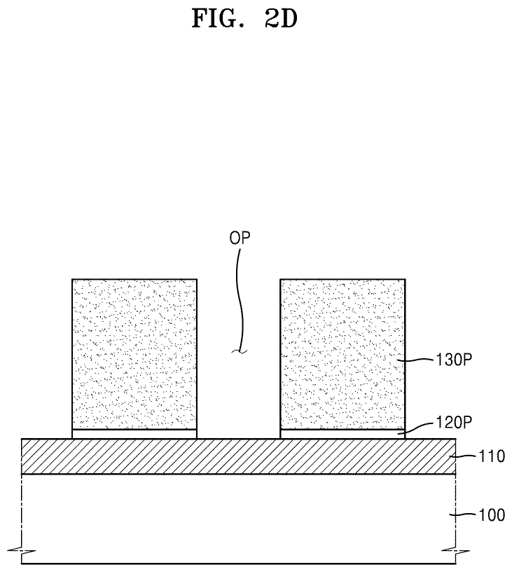

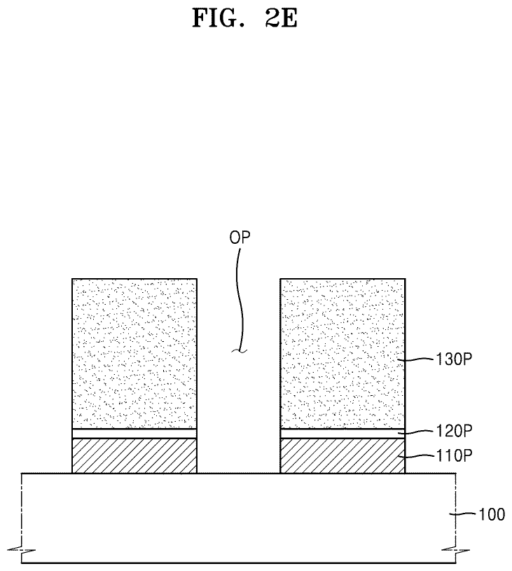

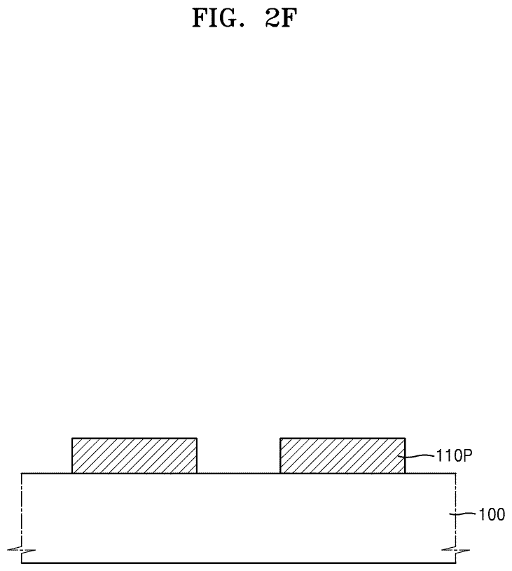

FIG. 1 is a flowchart illustrating a method of manufacturing an integrated circuit device, according to embodiments. FIGS. 2A to 2F are cross-sectional views respectively illustrating operations of a method of manufacturing an integrated circuit device, according to embodiments.

Hereinafter, the method of manufacturing an integrated circuit device, according to embodiments, is described with reference to FIGS. 1 and 2A to 2H.

Referring to FIGS. 1 and 2A, in operation P10, a device layer 110 may be formed on a substrate 100. Next, a resist lower film 120 may be formed on the device layer 110.

Next, in operation P20 of FIG. 1, a photoresist film 130 may be formed on the device layer 110 and the resist lower film 120 by using a photoresist composition according to embodiments of inventive concepts. A detailed configuration of the photoresist composition is the same as described above.

The substrate 100 may be an area in which a semiconductor device including a plurality of individual devices of various types is formed. The plurality of individual devices may include various microelectronic devices, for example, a metal-oxide-semiconductor field effect transistor (MOSFET) such as a complementary metal-insulator-semiconductor (CMOS) transistor, system large-scale integration (LSI), an image sensor such as a CMOS imaging sensor (CIS), a micro-electro-mechanical system (MEMS), an active element, a passive element, and the like. In some embodiments, the substrate 100 may include a semiconductor die area for forming a memory semiconductor chip or a logic circuit chip. For example, the semiconductor die area may be an area for forming a volatile memory semiconductor chip, such as dynamic random access memory (DRAM) or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

The device layer 110 may include a material for forming devices that are to be formed in the semiconductor die area. In some embodiments, the device layer 110 may include an insulating film or a conductive film. For example, the device layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

The resist lower film 120 may be arranged between the device layer 110 and the photoresist film 130 and may limit and/or prevent issues generated because irradiation rays reflected from under the photoresist film 130 are scattered to the photoresist film 130.

In some embodiments, the resist lower film 120 may include a developable bottom anti-reflective coating (DBARC) film. The DBARC film may control the diffuse reflection of light from a light source used in a light-exposure process or may absorb reflected light from the device layer 110 under the DBARC film. In some embodiments, the DBARC film may include an organic anti-reflective coating (ARC) material for a light source, such as a KrF excimer laser, an ArF excimer laser, an F₂ excimer laser, or an extreme ultraviolet (EUV) laser. In some embodiments, the DBARC film may include an organic component having a light-absorption structure. The light-absorption structure may include, for example, a hydrocarbon compound having a structure in which one or more benzene rings are fused.

In some embodiments, the resist lower film 120 may include a carbon-containing film. For example, the resist lower film 120 may include a carbon film, a doped carbon film, or an amorphous carbon layer (ACL). The doped carbon film may include a dopant including O, Si, N, W, B, I, C1, or a combination thereof.

The resist lower film 120 may have a thickness of about 1 nm to about 100 nm. To form the resist lower film 120, a plasma enhanced chemical vapor deposition (PECVD) process or an atomic layer deposition (ALD) process may be used, but inventive concepts are not limited thereto. In some embodiments, the resist lower film 120 may be omitted.

To form the photoresist film 130, the photoresist composition according to embodiments may be coated on the resist lower film 120. The coating set forth above may be performed by a method, such as spin coating, spray coating, dip coating, or the like. A process of heat-treating the photoresist composition may be performed at a temperature of about 80° C. to about 300° C. for about 10 seconds to about 100 seconds, but inventive concepts are not limited thereto. The thickness of the photoresist film 130 may be tens to hundreds of times the thickness of the resist lower film 120. The photoresist film 130 may have, but is not limited to, a thickness of about 10 nm to about 1 μm.

After the photoresist film 130 is formed, a soft bake process of the photoresist film 130 may be performed. The soft bake process of the photoresist film 130 may be performed at a temperature of about 50° C. to about 300° C. for about 10 seconds to about 100 seconds. While the soft bake process of the photoresist film 130 is being performed, a solvent in the photoresist film 130 may be volatilized, and adhesion between the photoresist film 130 and the resist lower film 120 may be increased.

Referring to FIGS. 1, 2B, and 2C, in operation P30, a first region 132, which is a portion of the photoresist film 130, may be exposed to light, and a post-exposure bake (PEB) process may be performed by applying heat 150 to the photoresist film 130 including the first region 132 that is exposed to light, thereby forming a heterogeneous inorganic network including heterogeneous inorganic elements from the organometallic oxide cluster that is included in the photoresist film 130 in the first region 132.

In some embodiments, to expose the first region 132 of the photoresist film 130 to light, a photomask 140, which has a plurality of light-shielding areas LS and a plurality of light-transmitting areas LT, may be aligned at a certain position over the photoresist film 130, and the first region 132 of the photoresist film 130 may be exposed to light through the plurality of light-transmitting areas LT of the photomask 140. To expose the first region 132 of the photoresist film 130 to light, a KrF excimer laser (248 nm), an ArF excimer laser (193 nm), an F₂ excimer laser (157 nm), or an EUV laser (13.5 nm) may be used.

In some embodiments, the photomask 140 may include a transparent substrate 142 and a plurality of light shielding patterns 144 formed in the plurality of light-shielding areas LS on the transparent substrate 142. The transparent substrate 142 may include quartz. The plurality of light shielding patterns 144 may include chromium (Cr). The plurality of light-transmitting areas LT may be defined by the plurality of light shielding patterns 144. According to inventive concepts, to expose the first region 132 of the photoresist film 130 to light, a reflective photomask (not shown) for EUV exposure may be used instead of the photomask 140.

The PEB process may be performed at a temperature of about 50° C. to about 400° C. for about 10 seconds to about 150 seconds. For example, the PEB process may be performed at a temperature of about 150° C. to about 250° C. for about 60 seconds to about 120 seconds, but inventive concepts are not limited thereto.

When the first region 132 of the photoresist film 130 is exposed to light, the first region 132 of the photoresist film 130 may absorb active energy rays, for example, EUV light, and thus, organic ligands may be dissociated from the organometallic oxide cluster in the photoresist film 130, thereby forming radicals. Then, while the PEB process is being performed, a condensation reaction of a hydroxyl (—OH) functional group may be induced in the first region 132, and as a result, the heterogeneous inorganic network having a dense structure and obtained by connecting the heterogeneous inorganic elements to each other by the medium of an oxygen atom may be formed.

In a second region 134, which is a non-light-exposed region of the photoresist film 130, the heterogeneous inorganic network is not formed, and the organometallic oxide cluster in the photoresist film 130 may be maintained in an original state without a structural change. Therefore, the difference in solubility in a developer between the first region 132 and the second region 134 of the photoresist film 130 may be increased.

Referring to FIGS. 1 and 2D, in operation P40, the second region 134 of the photoresist film 130 may be removed by developing the photoresist film 130 by using a developer. As a result, a photoresist pattern 130P, which includes the heterogeneous inorganic network formed in the light-exposed first region 132 of the photoresist film 130, may be formed.

A plurality of openings OP may be defined by the photoresist pattern 130P. In a plan view, each of the plurality of openings OP may have a line shape or a hole shape. After the photoresist pattern 130P is formed, a lower pattern 120P may be formed by removing portions of the lower film 120, which are exposed by the plurality of openings OP.

In some embodiments, the development of the photoresist film 130 may be performed by a negative-tone development (NTD) process. In some embodiments, to develop the photoresist film 130, a developer including an organic solvent may be used. For example, the developer may include, but is not limited to, PGMEA, PGME, MIBC, methyl ethyl ketone, acetone, cyclohexanone, 2-heptanone, 4-methyl-2-propanol, 1-butanol, isopropanol, 1-propanol, methanol, ethyl acetate, ethyl lactate, n-butyl acetate, butyrolactone, benzene, xylene, toluene, or a combination thereof.

As described with reference to FIG. 2C, as the difference in solubility in the developer between the light-exposed first region 132 and the non-light-exposed second region 134 in the photoresist film 130 is increased, while the second region 134 is being removed by developing the photoresist film 130 as described with reference to FIG. 2D, the first region 132 may remain intact without being removed. Therefore, after the photoresist film 130 is developed, residual defects, such as a footing phenomenon, may not occur, and a vertical sidewall profile of the photoresist pattern 130P may be obtained. Therefore, when the device layer 110 is processed by using the photoresist pattern 130P, a CD of an intended processing region in the device layer 110 may be more precisely controlled.

In some embodiments, after the photoresist pattern 130P is formed by developing the photoresist film 130 as described with reference to FIG. 2D, a process of performing hard bake on an obtained resulting product may be further performed. Through the hard bake process, unnecessary materials, such as the developer remaining on the resulting product in which the photoresist pattern 130P is formed, may be removed. The hard bake process may be performed at a temperature of about 50° C. to about 400° C. for about 10 seconds to about 150 seconds. For example, the hard bake process may be performed at a temperature of about 150° C. to about 250° C. for about 60 seconds to about 120 seconds, but inventive concepts are not limited thereto.

Referring to FIGS. 1 and 2E, in operation P50, in the resulting product of FIG. 2D, portions of the device layer 110 may be etched through the plurality of openings OP by using the photoresist pattern 130P as an etch mask, thereby forming a device pattern 110P.

Referring to FIG. 2F, the photoresist pattern 130P and the resist lower film 120, which remain on or over the device pattern 110P, may be removed.

According to the method of manufacturing an integrated circuit device, the method being described with reference to FIGS. 1 and 2A to 2F, a photoresist film may be formed by using a photoresist composition according to embodiments of inventive concepts, thereby providing improved and/or excellent coating properties when the photoresist film is formed. In addition, improved and/or sufficient etch selectivity and/or improved and/or sufficient mechanical strength may be secured in an etching process for manufacturing an integrated circuit device despite a reduction in the size and/or thickness of the photoresist pattern 130P, and process stability and/or reliability may improve during the process of manufacturing the integrated circuit device.

Next, synthesis examples of organometallic oxide clusters, which may be included in the photoresist composition according to embodiments, and various evaluation examples of the organometallic oxide clusters are described.

### Synthesis Example 1

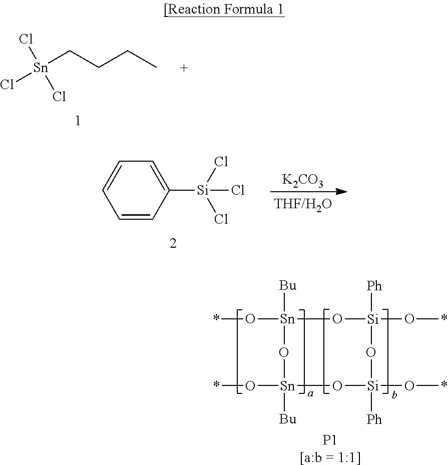

In Reaction Formula 1, Bu represents a n-butyl group, and Ph represents a phenyl group.

In Synthesis Example 1, a reaction between butyltin trichloride (that is, 1) and phenyltrichlorosilane (that is, 2) was performed at a molar ratio of 1:1. More specifically, 3.40 g (12.0 mmol) of butyltin trichloride corresponding to a reactant 1 and 2.55 g (12.0 mmol) of phenyltrichlorosilane corresponding to a reactant 2 were dissolved in 45 mL of tetrahydrofuran (THF) in a 175 mL culture tube having a screw cap and containing a magnetic stirring bar therein, and then, the solution was cooled to 0° C. A solution in which 5.00 g (36.0 mmol) of calcium carbonate was dissolved in 15 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The obtained filtrate was moved into a separatory funnel, followed by putting 30 mL of deionized water into the separatory funnel, and then, a water layer was extracted three times (50 mL X three times) with ethyl acetate. A collected organic layer was cleaned once with deionized water (30 mL), followed by introducing sodium sulfate thereto, and then dried. Next, the resultant was concentrated by a rotary vacuum evaporator and dried in a vacuum, thereby obtaining a product in the form of a white solid. The obtained product was additionally dried at 130° C. for 1 hour by using a vacuum oven, thereby obtaining a final product P1 in the form of a white solid. (yield 90%)

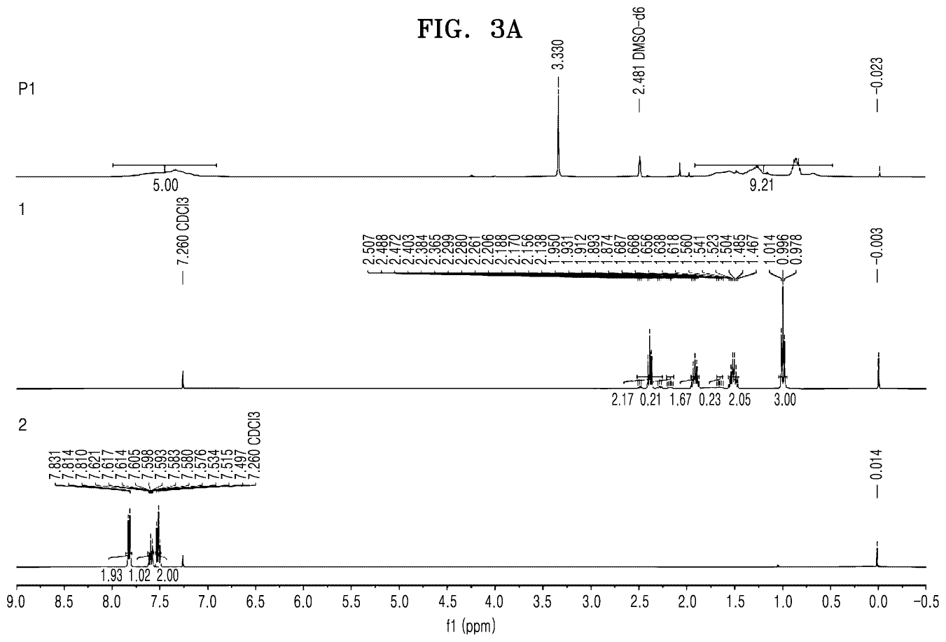

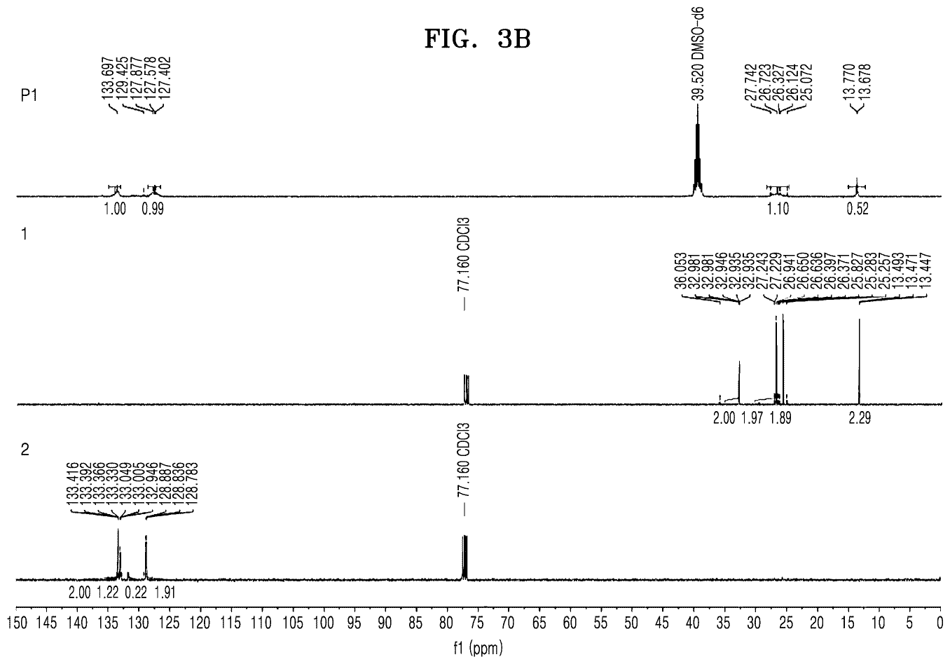

FIG. 3A is a ¹H-nuclear magnetic resonance spectroscopy (NMR) spectrum of each of the product P1 and the reactants 1 and 2 in Reaction Formula 1, and FIG. 3B is a ¹³C-NMR spectrum of each of the product P1 and the reactants 1 and 2 in Reaction Formula 1.

In FIGS. 3A and 3B, as a result of the NMR spectrum analysis of each of the product P1 and the reactants 1 and 2 in Reaction Formula 1, it may be confirmed from the broadened peaks in the product P1 that an intended product was synthesized.

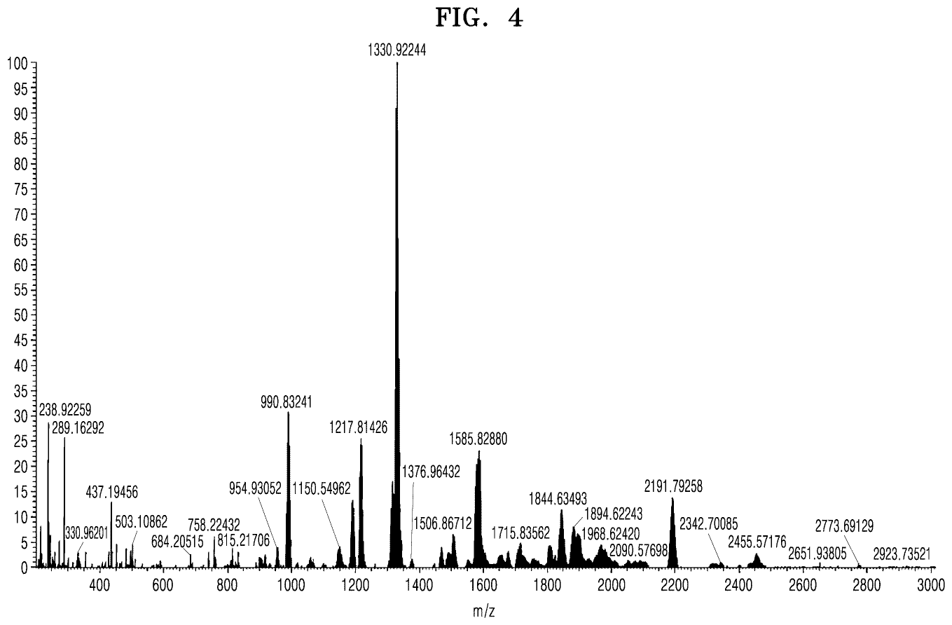

FIG. 4 is an electrospray ionization mass spectrometry (ESI-MS) spectrum of the product obtained in Reaction Formula 1.

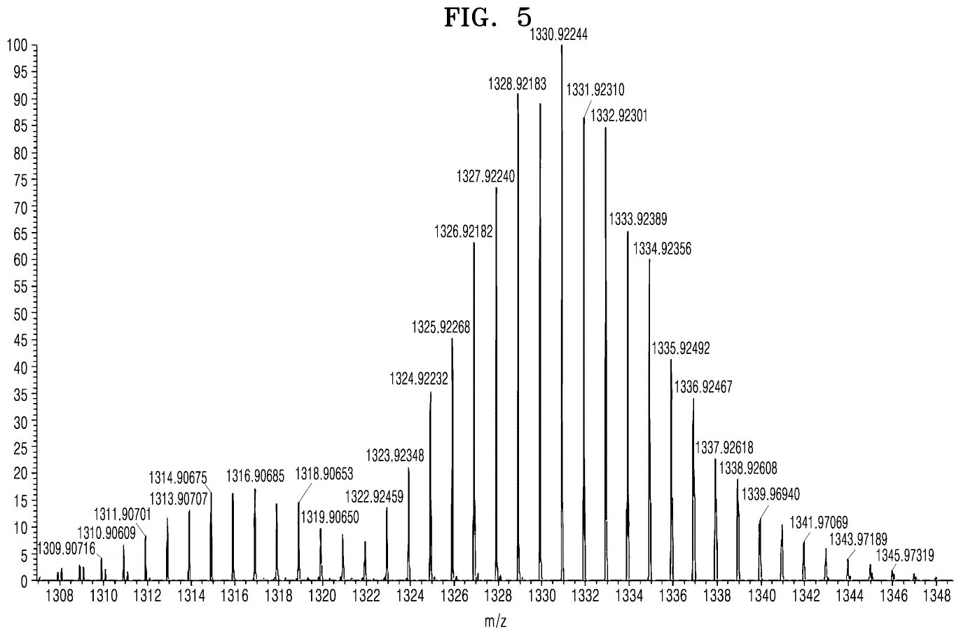

FIG. 5 is a spectrum obtained by enlarging the peak at a mass-to-charge ratio (m/z)=1330 in the ESI-MS spectrum of FIG. 4. From the peak shape shown in FIG. 5, it may be seen that the product P1 in Reaction Formula 1 includes both tin and silicon.

### Synthesis Example 2

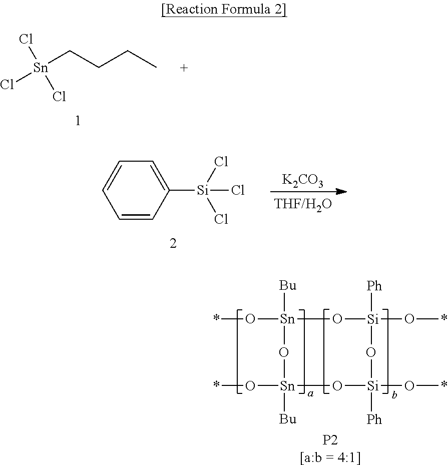

In Reaction Formula 2, Bu represents a n-butyl group, and Ph represents a phenyl group.

In Synthesis Example 2, substantially the same processes as in Synthesis Example 1 were performed. However, the reaction between butyltin trichloride corresponding to the reactant 1 and phenyltrichlorosilane corresponding to the reactant 2 was performed at a molar ratio of about 4:1. As the amount of butyltin trichloride corresponding to the reactant 1 that includes tin, out of the reactants 1 and 2, increases, the EUV photosensitivity of a product P2 that is finally obtained may improve. More specifically, 5.42 g (19.2 mmol) of butyltin trichloride corresponding to the reactant 1 and 1.02 g (4.82 mmol) of phenyltrichlorosilane corresponding to the reactant 2 were dissolved in 45 mL of THF in a 175 mL culture tube having a screw cap and containing a magnetic stirring bar therein, and then, the solution was cooled to 0° C. A solution in which 5.00 g (36.0 mmol) of calcium carbonate was dissolved in 15 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The obtained filtrate was moved into a separatory funnel, followed by putting 30 mL of deionized water into the separatory funnel, and then, a water layer was extracted three times (50 mL X three times) with ethyl acetate. A collected organic layer was cleaned once with deionized water (30 mL), followed by introducing sodium sulfate thereto, and then dried. Next, the resultant was concentrated by a rotary vacuum evaporator and dried in a vacuum, thereby obtaining a product in the form of a white solid. The obtained product was additionally dried at 130° C. for 1 hour by using a vacuum oven, thereby obtaining the final product P2 in the form of a white solid. (yield 96%)

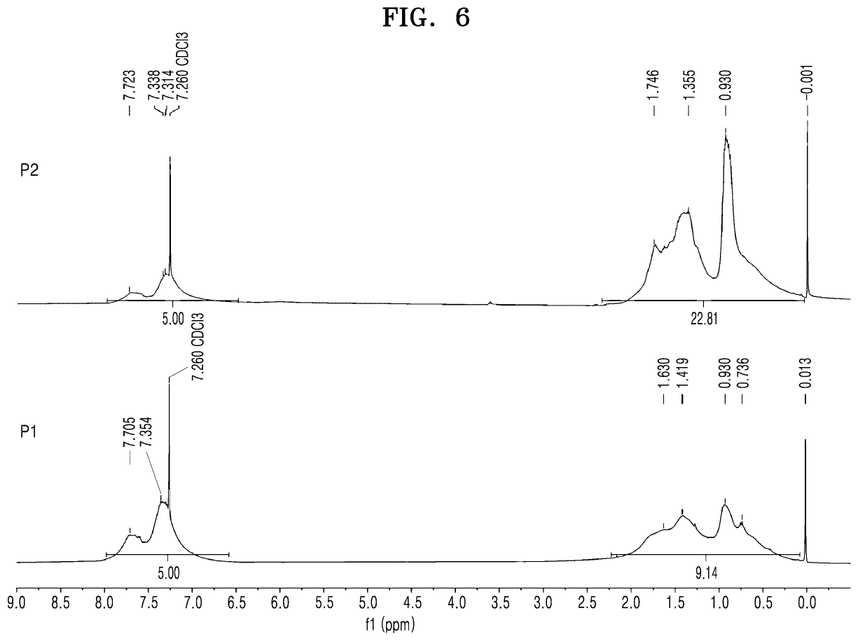

FIG. 6 is a ¹H-NMR spectrum of each of the product P1 obtained in Synthesis Example 1 and the product P2 obtained in Synthesis Example 2.

From FIG. 6, it may be confirmed that the integral value of the peak corresponding to a ligand (a butyl group) bonded to tin is increased in the ¹H-NMR spectrum of the product P2 obtained in Synthesis Example 2 as compared with the ¹H-NMR spectrum of the product P1 obtained in Synthesis Example 1. From this result, it may be seen that the content ratio of tin in the product P2 obtained in Synthesis Example 2 is greater than the content ratio of tin in the product P1 obtained in Synthesis Example 1.

### Synthesis Example 3

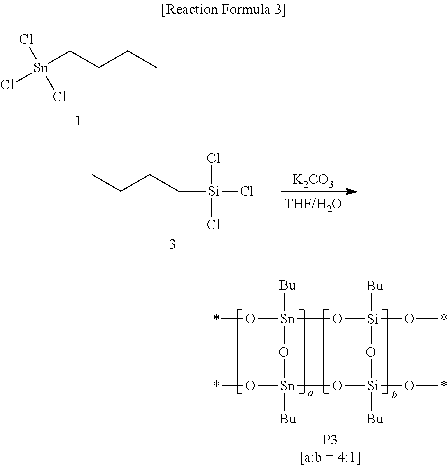

In Reaction Formula 3, Bu represents a n-butyl group.

In Synthesis Example 3, substantially the same processes as in Synthesis Example 2 were performed. However, butyltrichlorosilane corresponding to a reactant 3 was used instead of phenyltrichlorosilane corresponding to the reactant 2. More specifically, 5.42 g (19.2 mmol) of butyltin trichloride corresponding to the reactant 1 and 0.92 g (4.8 mmol) of butyltrichlorosilane corresponding to the reactant 3 were dissolved in 45 mL of THF in a 175 mL culture tube having a screw cap and containing a magnetic stirring bar therein, and then, the solution was cooled to 0° C. A solution in which 5.00 g (36.0 mmol) of calcium carbonate was dissolved in 15 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The filtrate was moved into a separatory funnel, followed by putting 30 mL of deionized water into the separatory funnel, and then, a water layer was extracted three times (50 mL X three times) with ethyl acetate. A collected organic layer was cleaned once with deionized water (30 mL), followed by introducing sodium sulfate thereto, and then dried. Next, the resultant was concentrated by a rotary vacuum evaporator and dried in a vacuum, thereby obtaining a product in the form of a white solid. The obtained product was additionally dried at 130° C. for 1 hour by using a vacuum oven, thereby obtaining a final product P3 in the form of a white solid. (yield 76%)

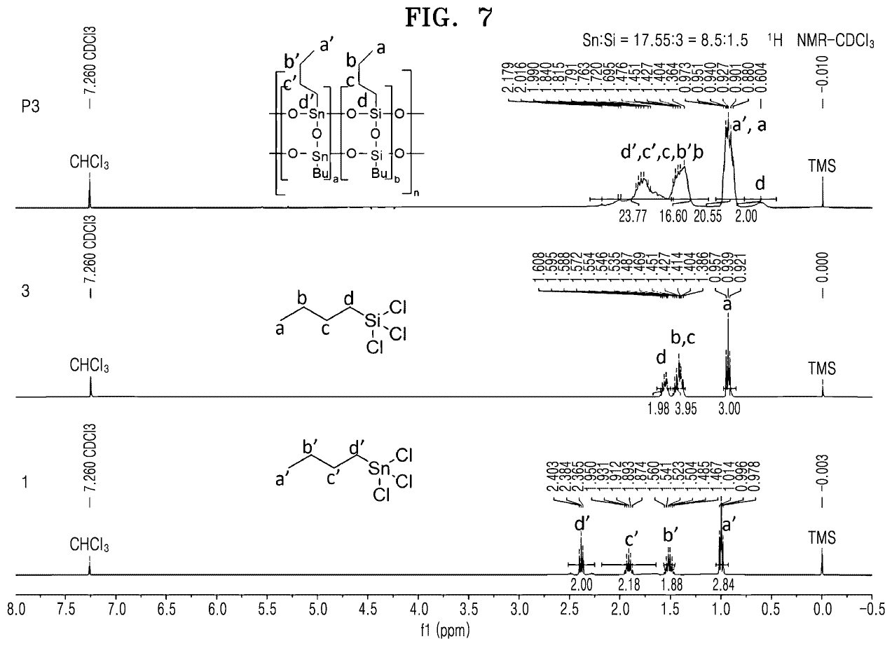

FIG. 7 is a ¹H-NMR spectrum of each of the product P3 and the reactants 1 and 3 in Reaction Formula 3. As a result of the analysis of an integral value of the ¹H-NMR spectrum of FIG. 7, the molar ratio between tin and silicon in the product P3 was about 8.5:1.5. In FIG. 7, as a result of the NMR spectrum analysis of each of the product P3 and the reactants 1 and 3 in Reaction Formula 3, it may be confirmed from the broadened peaks in the product P3 that an intended product was synthesized.

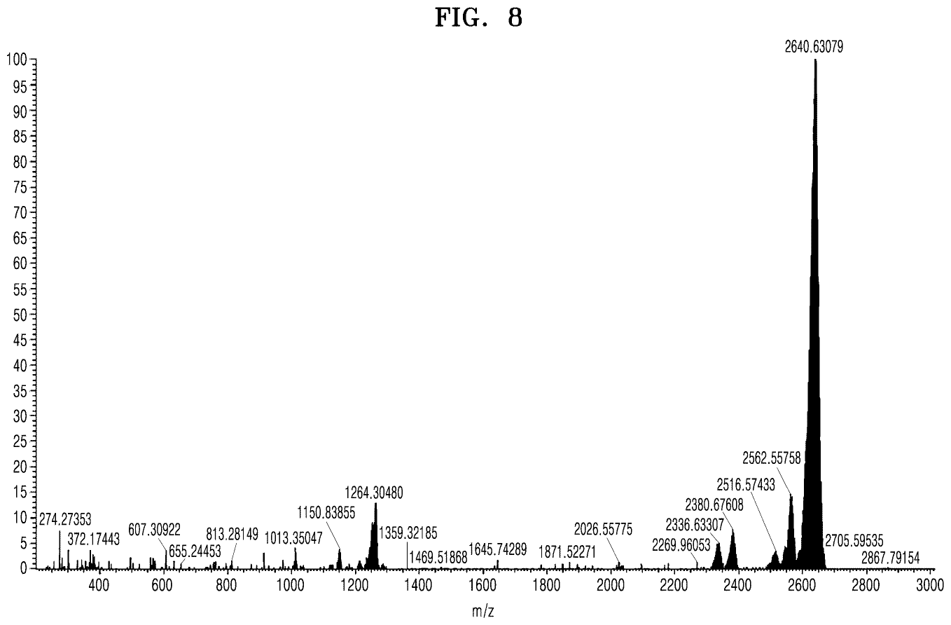

FIG. 8 is an ESI-MS spectrum of the product P3 obtained in Reaction Formula 3.

### Synthesis Example 4

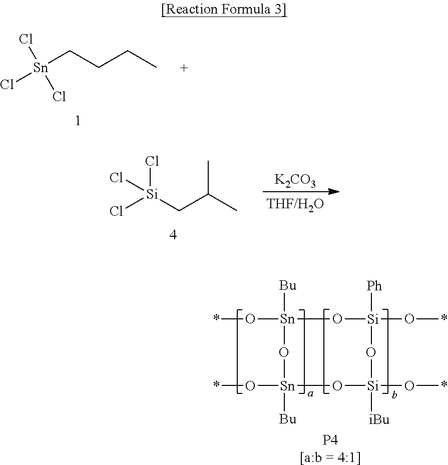

In Reaction Formula 4, Bu represents a n-butyl group, and iBu represents an isobutyl group.

In Synthesis Example 4, substantially the same processes as in Synthesis Example 2 were performed. However, isobutyltrichlorosilane corresponding to a reactant 4 was used instead of phenyltrichlorosilane corresponding to the reactant 2. More specifically, 5.42 g (19.2 mmol) of butyltin trichloride corresponding to the reactant 1 and 0.92 g (4.8 mmol) of isobutyltrichlorosilane corresponding to the reactant 4 were dissolved in 45 mL of THF in a 175 mL culture tube having a screw cap and containing a magnetic stirring bar therein, and then, the solution was cooled to 0° C. A solution in which 5.00 g (36.0 mmol) of calcium carbonate was dissolved in 15 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The obtained filtrate was moved into a separatory funnel, followed by putting 30 mL of deionized water into the separatory funnel, and then, a water layer was extracted three times (50 mL X three times) with ethyl acetate. A collected organic layer was cleaned once with deionized water (30 mL), followed by introducing sodium sulfate thereto, and then dried. Next, the resultant was concentrated by a rotary vacuum evaporator and dried in a vacuum, thereby obtaining a product in the form of a white solid. The obtained product was additionally dried at 130° C. for 1 hour by using a vacuum oven, thereby obtaining a final product P4 in the form of a white solid. (yield 96%)

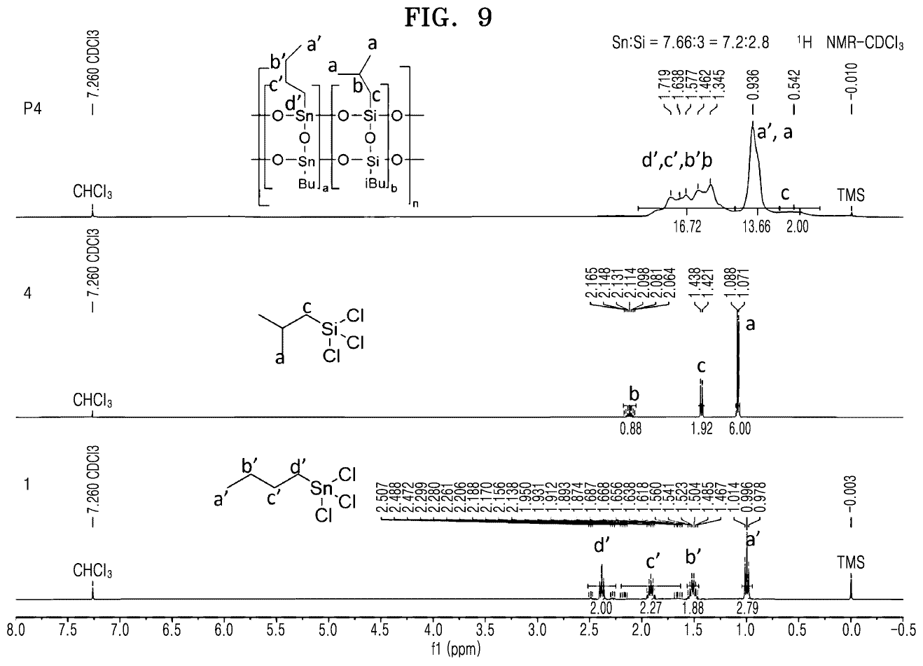

FIG. 9 is a ¹H-NMR spectrum of each of the product P4 and the reactants 1 and 4 in Reaction Formula 4. As a result of the analysis of an integral value of the ¹H-NMR spectrum of FIG. 9, the molar ratio between tin and silicon in the product P4 was about 7.2:2.8. In FIG. 9, as a result of the NMR spectrum analysis of each of the product P4 and the reactants 1 and 4 in Reaction Formula 4, it may be confirmed from the broadened peaks in the product P4 that an intended product was synthesized.

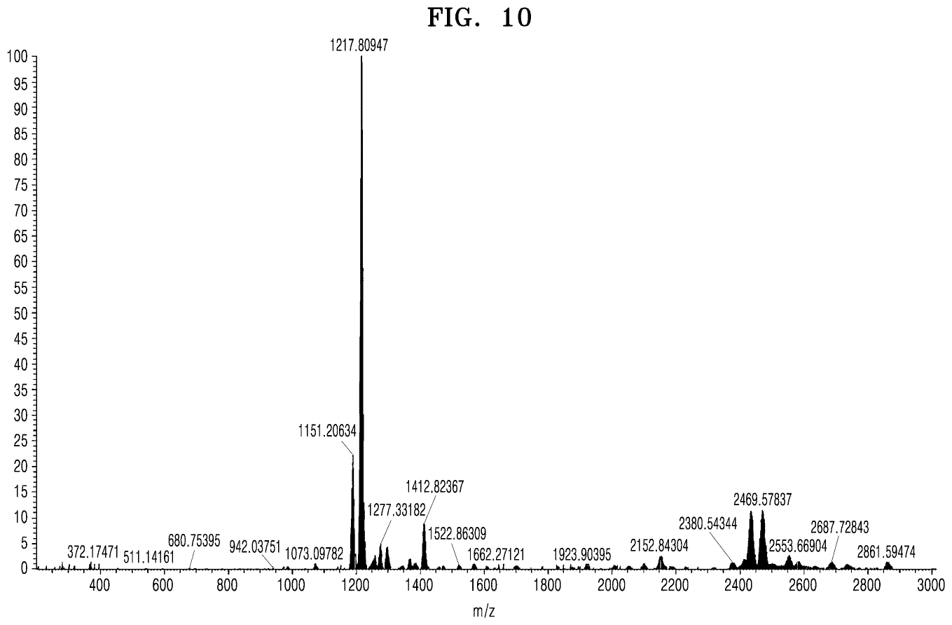

FIG. 10 is an ESI-MS spectrum of the product P4 obtained in Reaction Formula 4.

### Synthesis Example 5

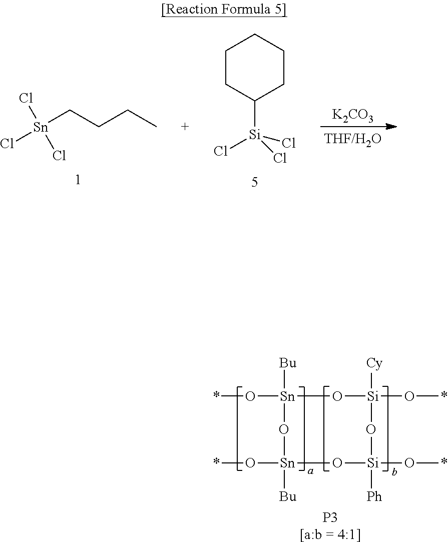

In Reaction Formula 5, Bu represents a n-butyl group, and Cy represents a cyclohexyl group.

In Synthesis Example 5, substantially the same processes as in Synthesis Example 2 were performed. However, cyclohexyltrichlorosilane corresponding to a reactant 5 was used instead of phenyltrichlorosilane corresponding to the reactant 2. More specifically, 5.42 g (19.2 mmol) of butyltin trichloride corresponding to the reactant 1 and 1.04 g (4.78 mmol) of cyclohexyltrichlorosilane corresponding to the reactant 5 were dissolved in 45 mL of THF in a 175 mL culture tube having a screw cap and containing a magnetic stirring bar therein, and then, the solution was cooled to 0° C. A solution in which 5.00 g (36.0 mmol) of calcium carbonate was dissolved in 15 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The filtrate was moved into a separatory funnel, followed by putting 30 mL of deionized water into the separatory funnel, and then, a water layer was extracted three times (50 mL X three times) with ethyl acetate. A collected organic layer was cleaned once with deionized water (30 mL), followed by introducing sodium sulfate thereto, and then dried. Next, the resultant was concentrated by a rotary vacuum evaporator and dried in a vacuum, thereby obtaining a product in the form of a white solid. The obtained product was additionally dried at 130° C. for 1 hour by using a vacuum oven, thereby obtaining a final product P5 in the form of a white solid. (yield 90%)

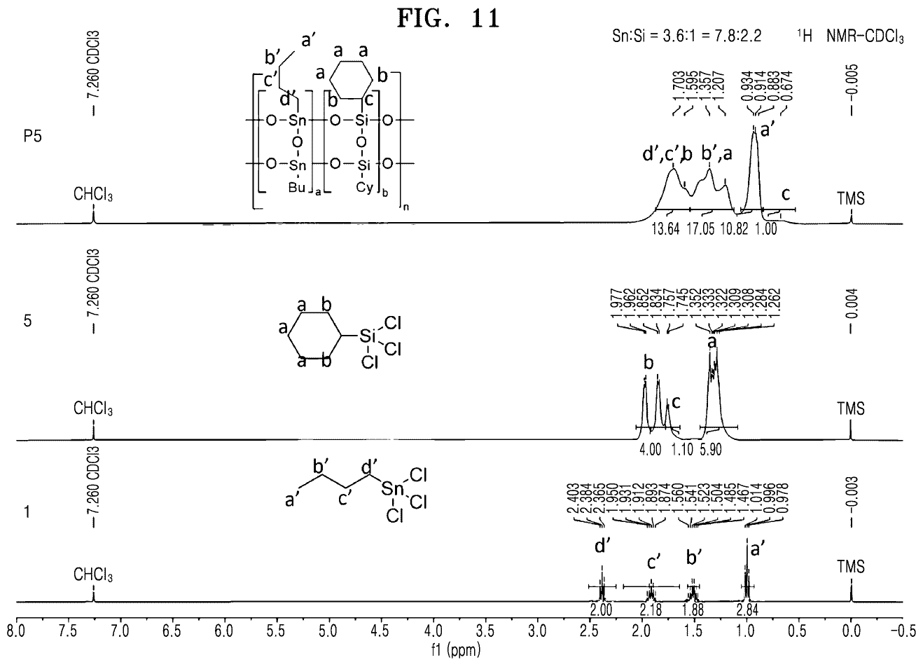

FIG. 11 is a ¹H-NMR spectrum of each of the product P5 and the reactants 1 and 5 in Reaction Formula 5. As a result of the analysis of an integral value of the ¹H-NMR spectrum of FIG. 11, the molar ratio between tin and silicon in the product P5 was about 7.8:2.2. In FIG. 11, as a result of the NMR spectrum analysis of each of the product P5 and the reactants 1 and 5 in Reaction Formula 5, it may be confirmed from the broadened peaks in the product P5 that an intended product was synthesized.

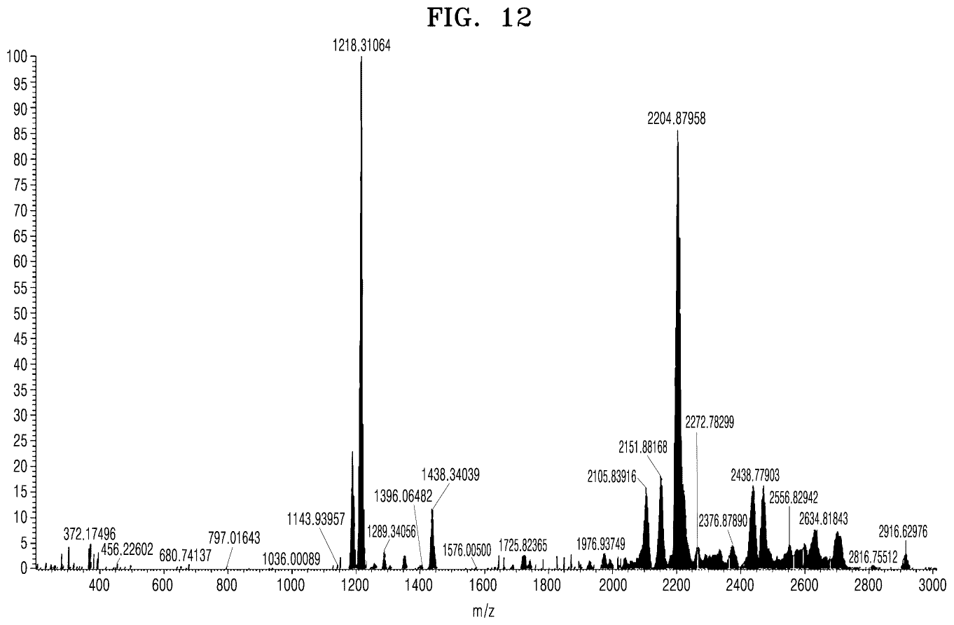

FIG. 12 is an ESI-MS spectrum of the product P5 obtained in Reaction Formula 5.

### Synthesis Example 6

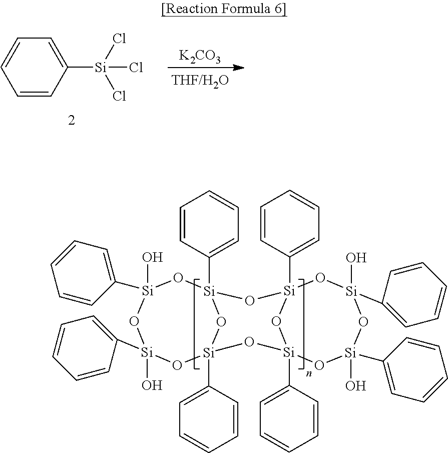

0.500 g (2.36 mmol) of phenyltrichlorosilane corresponding to the reactant 2 was dissolved in 6 mL of THF in a 30 mL culture tube having a screw cap and containing a magnetic stirring bar therein, followed by cooling the solution to 0° C. A solution in which 0.980 g (7.09 mmol) of calcium carbonate was dissolved in 2 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The filtrate was moved into a separatory funnel, followed by putting 5 mL of deionized water into the separatory funnel, and then, a water layer was extracted three times (50 mL X three times) with ethyl acetate. A collected organic layer was cleaned once with deionized water (10 mL), followed by introducing sodium sulfate thereto, and then dried. Next, the resultant was concentrated by a rotary vacuum evaporator and dried in a vacuum, thereby obtaining a comparative product R1 in the form of a transparent solid. (yield 80%)

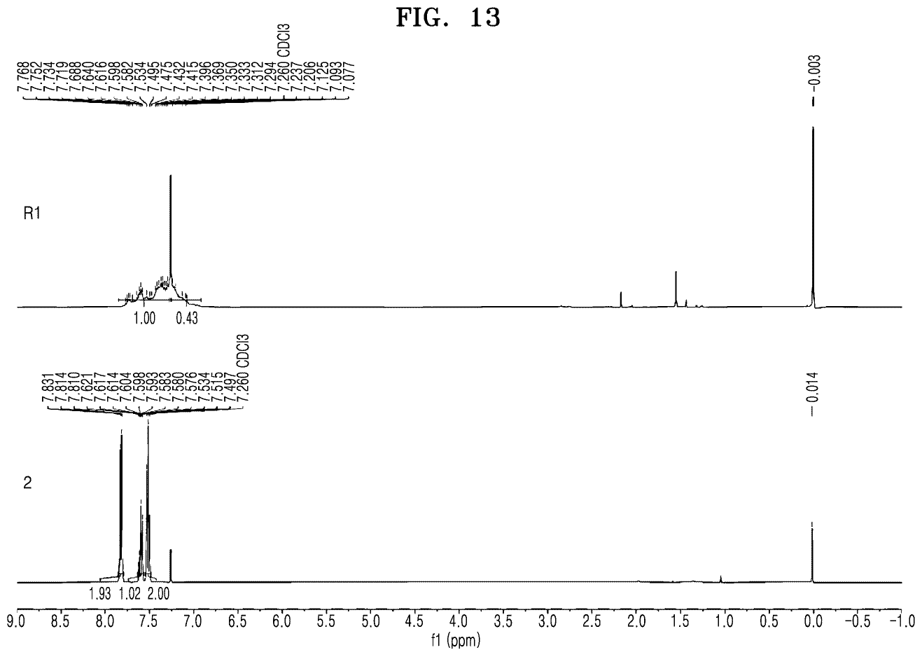

FIG. 13 is a ¹H-NMR spectrum of each of the comparative product R1 and the reactant 2 in Reaction Formula 6.

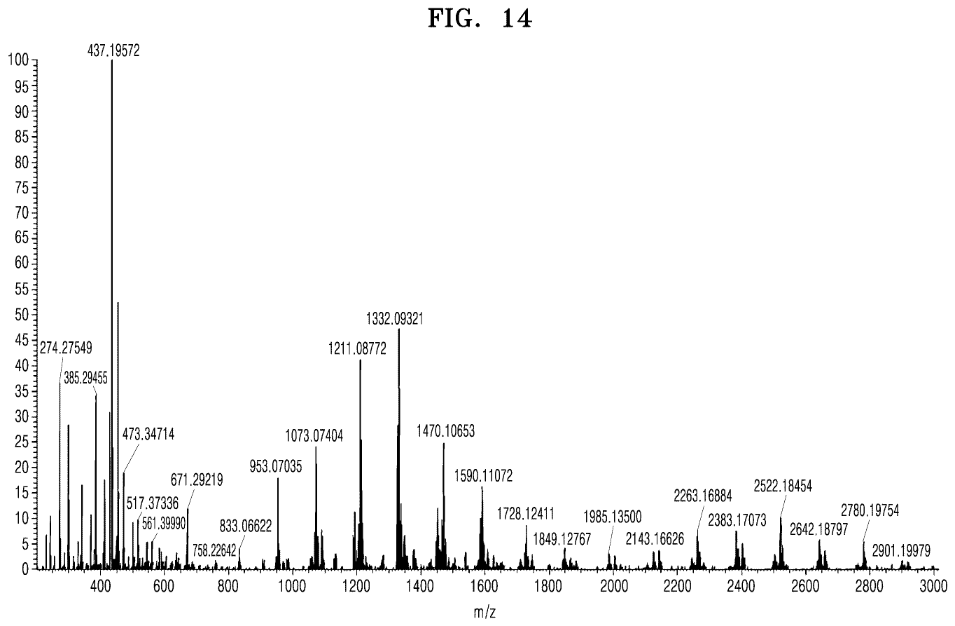

FIG. 14 is an ESI-MS spectrum of the comparative product R1 obtained in Reaction Formula 6.

### Synthesis Example 7

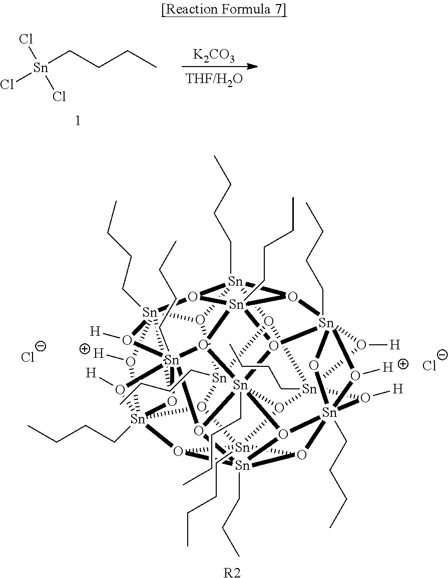

0.500 g (1.77 mmol) of butyltin trichloride corresponding to the reactant 1 was dissolved in 6 mL of THF in a 30 mL culture tube having a screw cap and containing a magnetic stirring bar therein, followed by cooling the solution to 0° C. A solution in which 0.735 g (5.32 mmol) of calcium carbonate was dissolved in 2 mL of water was slowly added to the obtained resulting product while being stirred. Next, the culture tube was blocked with the screw cap, and the components were stirred at 40° C. for 5 days. Next, the reaction mixture was filtered, thereby removing remaining solids. The filtrate was moved into a separatory funnel, followed by putting 5 mL of deionized water into the separatory funnel, and then, a water layer was extracted three times (50 mL X three times) with ethyl acetate. A collected organic layer was cleaned once with deionized water (10 mL), followed by introducing sodium sulfate thereto, and then dried. Next, the resultant was concentrated by a rotary vacuum evaporator and dried in a vacuum, thereby obtaining a comparative product R2 in the form of a transparent solid. (yield 90%)

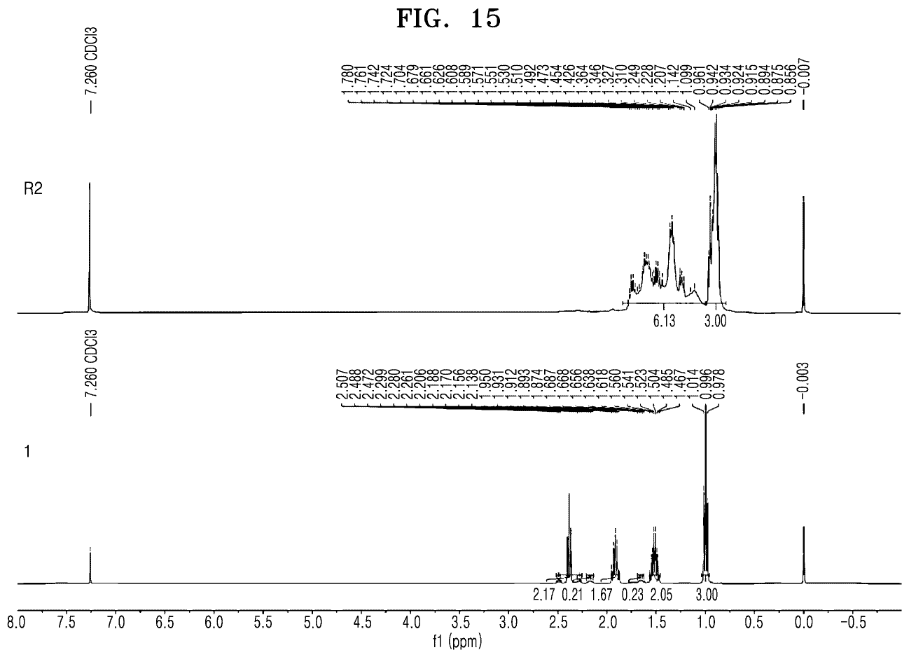

FIG. 15 is a ¹H-NMR spectrum of each of the comparative product R2 and the reactant 1 in Reaction Formula 7.

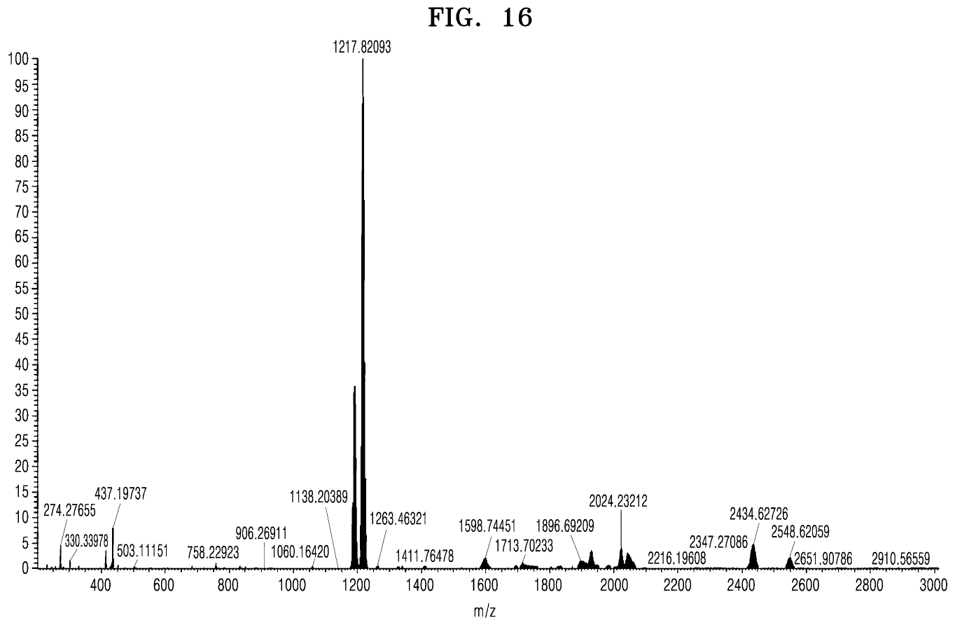

FIG. 16 is an ESI-MS spectrum of the comparative product R2 obtained in Reaction Formula 7.

When respective results of the NMR analysis of the comparative product R1 of Synthesis Example 6 in FIG. 13 and the NMR analysis of the comparative product R2 of Synthesis Example 7 in FIG. 15 are compared with the result of the NMR analysis of the product P1 of Synthesis Example 1 in FIG. 3A, the NMR analysis result of the product P1 of Synthesis Example 1 shows a different shape from that of the NMR analysis result of each of the comparative products R1 and R2. From this result, it may be seen that tin and silicon, which are heterogeneous inorganic elements, are mixed in the product P1 of Synthesis Example 1.

In addition, when respective analysis results of the ESI-MS spectrum of the comparative product R1 of Synthesis Example 6 in FIG. 4 and the ESI-MS spectrum of the comparative product R2 of Synthesis Example 7 in FIG. 16 are compared with the analysis result of the ESI-MS spectrum of the product P1 of Synthesis Example 1 in FIG. 3B, it may be confirmed that the ESI-MS spectrum of the product P1 of Synthesis Example 1 shows a different shape from that of the ESI-MS spectrum of each of the comparative products R1 and R2.

### Evaluation Example 1

### Evaluation of Solubility

Each of the products (that is, P1, P2, P3, P4, P5, R1, and R2) synthesized in Synthesis Examples 1 to 7 was dissolved in PGMEA, PGME, and MIBC, followed by checking the weight (the weight ratio in a solvent) of each thereof when each product was dissolved to the maximum, thereby measuring the solubility of each product.

Evaluation results are shown in Table 1. In Table 1, “−” indicates that the solubility was not measured.

TABLE 1

| | | Solubility (wt %) | | |
|---|---|---|---|---|
| Example | Product | PGMEA | PGME | MIBC |
| Example 1 | P1 | 26 | 27 | — |
| Example 2 | P2 | 41 | — | — |
| Example 3 | P3 | Insoluble | Insoluble | 29 |
| | | materials | materials | |
| | | present | present | |
| Example 4 | P4 | Insoluble | Insoluble | 35 |
| | | materials | materials | |
| | | present | present | |
| Example 5 | P5 | Insoluble | Insoluble | 32 |
| | | materials | materials | |
| | | present | present | |
| Comparative | R1 | 22 | 24 | — |
| Example 1 | | | | |
| Comparative | R2 | 4 | 3 | 5 |
| Example 2 | | | | |

From the results of Table 1, it may be seen that the products P1, P2, P3, P4, and P5 of Examples 1 to 5 have improved solubility in at least one developer among PGMEA, PGME, or MIBC, than the comparative products R1 and R2 of Comparative Examples 1 and 2.

### Evaluation Example 2

### Formation of Photoresist Pattern

Each of the product P3, P4, and P5 synthesized in Synthesis Examples 3 to 5 was dissolved to 2.5 wt % in MIBC, followed by coating the resultant on a wafer. Next, each of the obtained resulting products underwent a soft bake process at 110° C. for 1 minute, followed by performing an exposure process thereon for forming a line-and-space pattern at various exposure energy doses by using an electron beam, and then underwent a PEB process at 170° C. for 1 minute. Next, each of the obtained resulting products was developed by immersion in PGMEA for 30 seconds, thereby forming photoresist patterns including the line-and-space pattern.

Table 2 shows various exposure energy doses applied in the exposure process to form a photoresist pattern from a photoresist composition including each of the product P3, P4, and P5 synthesized in Synthesis Examples 3 to 5, and results of evaluating whether the photoresist pattern is formed under the conditions of the various exposure energy doses. In Table 2, “X” indicates that the photoresist pattern is not formed, and “O” indicates that the photoresist pattern is formed.

TABLE 2

| | | Exposure energy dose (μC/cm²) | | | | | | |
|---|---|---|---|---|---|---|---|---|
| Example | Product | 100 | 400 | 600 | 1000 | 2000 | 3000 | 4000 |
| Example 6 | P3 | X | X | X | ◯ | ◯ | ◯ | ◯ |
| Example 7 | P4 | X | X | X | ◯ | ◯ | ◯ | ◯ |
| Example 8 | P5 | X | X | X | ◯ | ◯ | ◯ | ◯ |

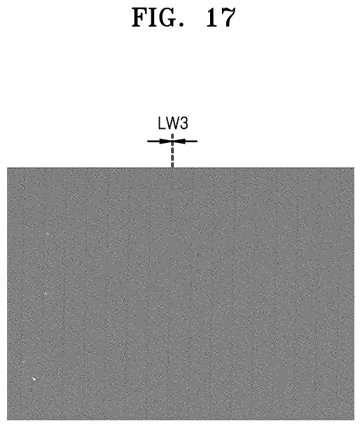

FIGS. 17 to 19 are each a scanning electron microscope (SEM) image of a photoresist pattern obtained from a photoresist composition according to embodiments.

More specifically, FIG. 17 is an SEM image of the photoresist pattern obtained by performing light-exposure at an exposure energy dose of 2000 μC/cm² on the photoresist composition including the product P3 obtained in Synthesis Example 3, according to Example 6. In FIG. 17, a line-width LW3 of the photoresist pattern is 31 nm.

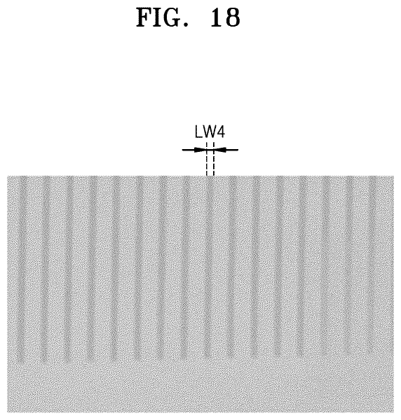

FIG. 18 is an SEM image of the photoresist pattern obtained by performing light-exposure at an exposure energy dose of 2000 μC/cm² on the photoresist composition including the product P4 obtained in Synthesis Example 4, according to Example 7. In FIG. 18, a line-width LW4 of the photoresist pattern is 420 nm.

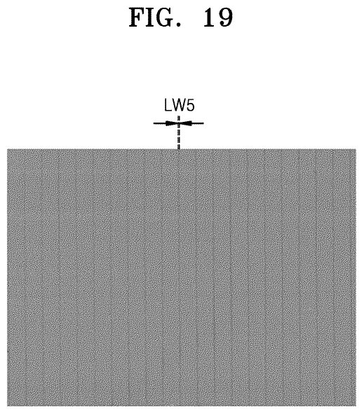

FIG. 19 is an SEM image of the photoresist pattern obtained by performing light-exposure at an exposure energy dose of 2000 μC/cm² on the photoresist composition including the product P5 obtained in Synthesis Example 5, according to Example 8. In FIG. 19, a line-width LW5 of the photoresist pattern is 53.4 nm.

From the results of Table 2 and FIGS. 17 to 19, it may be seen that, when a photoresist film is formed through a photolithography process by using the photoresist composition that includes each of the products P3, P4, and P5 having heterogeneous inorganic elements and respectively synthesized in Synthesis Examples 3 to 5, a good and/or improved photoresist pattern may be formed at an exposure energy dose of 1000 μC/cm² to 4000 μC/cm².

While inventive concepts has been particularly shown and described with reference to embodiments thereof, it will be understood that various changes in form and details may be made therein without departing from the spirit and scope of the following claims.

What is claimed is:

1. A photoresist composition comprising:
an organometallic oxide cluster; and
a solvent, wherein
the organometallic oxide cluster comprises a copolymer comprising a first repeating unit represented by General Formula 1 and a second repeating unit represented by General Formula 2, 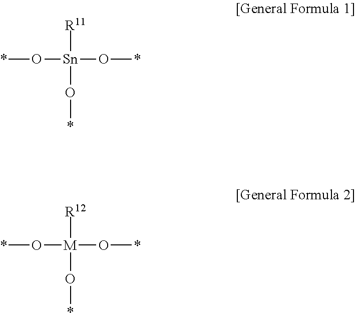
wherein, in General Formulae 1 and 2,
R¹¹ and R¹² are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R¹¹ and R¹² has a substituent, the substituent includes at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
* represents a binding site, and
in General Formula 2,
M is Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

2. The photoresist composition of claim 1, wherein the organometallic oxide cluster comprises one or more repeating units represented by General Formula 3: 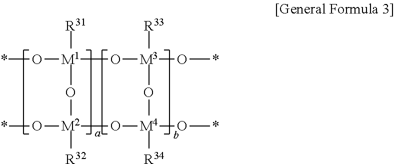
wherein, in General Formula 3,
one, two, or three of M¹, M², M³, and M⁴ are Sn, and
others, which are not Sn, among M¹, M², M³, and M⁴ independently are Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
R³¹, R³², R³³, and R³⁴ are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group, or
each of R³¹, R³², R³³, and R³⁴ independently includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
a/(a+b) and b/(a+b) are each 0.05 to 0.95, and
* represents a binding site.

3. The photoresist composition of claim 2, wherein, in General Formula 3,
one, two, or three of M¹, M², M³, and M⁴ are Sn, and
others, which are not Sn, among M¹, M², M³, and M⁴ are Si.

4. The photoresist composition of claim 3, wherein
in the organometallic oxide cluster, a molar ratio of Sn is equal to a molar ratio of Si.

5. The photoresist composition of claim 3, wherein,
in the organometallic oxide cluster, a molar ratio of Sn is greater than a molar ratio of Si.

6. The photoresist composition of claim 1, wherein the organometallic oxide cluster comprises one or more repeating units represented by General Formula 4: 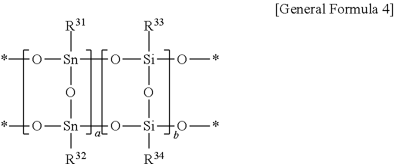
wherein, in General Formula 4,
R³¹, R³², R³³, and R³⁴ are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R³¹, R³², R³³, and R³⁴ has a substituent, the substituent includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
a/(a+b) and b/(a+b) are each 0.05 to 0.95, and
* represents a binding site.

7. The photoresist composition of claim 6, wherein, in General Formula 4, R³¹, R³², R³³, and R³⁴ are each independently a C1-C30 linear alkyl group, a C1-C30 branched alkyl group, a C3-C30 cycloalkyl group, a C6-C30 aryl group, or a C7-C30 alkylaryl group.

8. A photoresist composition comprising:
an organometallic oxide cluster; and
a solvent, wherein
the organometallic oxide cluster comprises a copolymer comprising a first repeating unit represented by General Formula 1 and a second repeating unit represented by General Formula 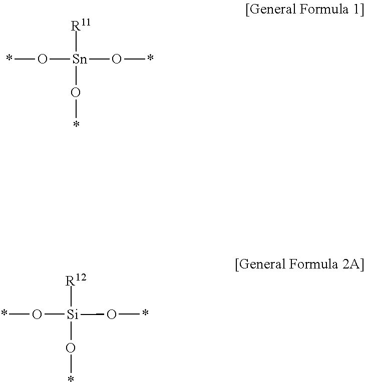
wherein, in Formulae 1 and 2A,
R¹¹ and R¹² are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R¹¹ and R¹² has a substituent, the substituent includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof, and
* represents a binding site.

9. The photoresist composition of claim 8, wherein the organometallic oxide cluster comprises one or more repeating units represented by General Formula 4: 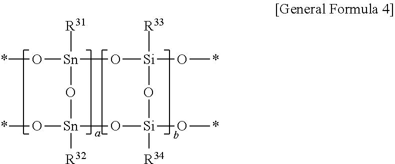
wherein, in General Formula 4,
R³¹, R³², R³³, and R³⁴ are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R³¹, R³², R³³, and R³⁴ has a substituent, the substituent include a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
a/(a+b) and b/(a+b) are each 0.05 to 0.95, and
* represents a binding site.

10. The photoresist composition of claim 9, wherein, in General Formula 4, R³¹, R³², R³³, and R³⁴ are each independently a C1-C30 linear alkyl group, a C1-C30 branched alkyl group, a C3-C30 cycloalkyl group, a C6-C30 aryl group, or a C7-C30 alkylaryl group.

11. A method of manufacturing an integrated circuit device, the method comprising:
forming a device layer on a substrate;
forming a photoresist film on the device layer using a photoresist composition, the photoresist composition including an organometallic oxide cluster and a solvent;
forming a heterogeneous inorganic network from the organometallic oxide cluster in a first region of the photoresist film by exposing the first region of the photoresist film to light, the first region of the photoresist film being a portion of the photoresist film;
forming a photoresist pattern comprising the heterogeneous inorganic network by developing the photoresist film comprising the first region that is exposed to light; and
etching the device layer using the photoresist pattern as a mask, wherein
in the forming the photoresist film, the organometallic oxide cluster comprises a copolymer includes a first repeating unit represented by General Formula 1 and a second repeating unit represented by General Formula 2, 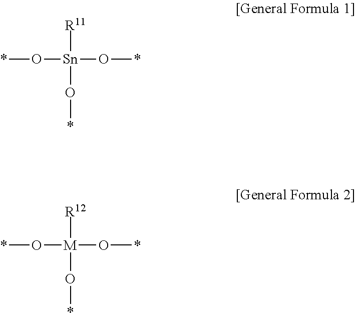
wherein, in General Formulae 1 and 2,
R¹¹ and R¹² are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R¹¹ and R¹² has a substituent, the substituent includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
* represents a binding site, and,
in General Formula 2,
M is Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

12. The method of claim 11, wherein,
in the forming the photoresist film, the organometallic oxide cluster comprises one or more repeating units represented by General Formula 3: 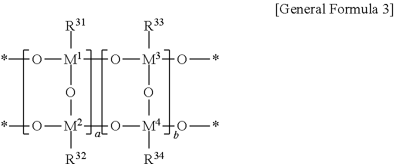
wherein, in General Formula 3,
one, two, or three of M¹, M², M³, and M⁴ are Sn,
others, which are not Sn, among M¹, M², M³, and M⁴ independently are Si, Ge, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
R³¹, R³², R³³, and R³⁴ are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R³¹, R³², R³³, and R³⁴ has a substituent, the substituent includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
a/(a+b) and b/(a+b) are each 0.05 to 0.95, and
* represents a binding site.

13. The method of claim 12, wherein, in General Formula 3,
one, two, or three among M¹, M², M³, and M⁴ are Sn, and
others, which are not Sn, among M¹, M², M³, and M⁴ are Si.

14. The method of claim 13, wherein,
in the organometallic oxide cluster, a molar ratio of Sn is equal to a molar ratio of Si.

15. The method of claim 13, wherein,
in the organometallic oxide cluster, a molar ratio of Sn is greater than a molar ratio of Si.

16. The method of claim 11, wherein, in the forming the photoresist film, the organometallic oxide cluster comprises one or more repeating units represented by General Formula 4: 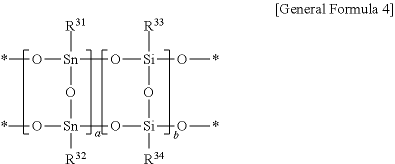
wherein, in General Formula 4,
R³¹, R³², R³³, and R³⁴ are each independently a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a disubstituted phosphoric acid group, an R²COO— group, an R²SO₃— group, or an R²SO₂— group, wherein R² is a substituted or unsubstituted C1-C10 alkyl group or a substituted or unsubstituted phenyl group,
when at least one of R³¹, R³², R³³, and R³⁴ has a substituent, the substituent includes a hydrocarbyl group that is substituted with at least one heteroatom functional group comprising an oxygen atom, a nitrogen atom, a halogen element, a cyano group, a thio group, a silyl group, an ether group, a carbonyl group, an ester group, a nitro group, an amino group, or a combination thereof,
a/(a+b) and b/(a+b) are each 0.05 to 0.95, and
* represents a binding site.

17. The method of claim 16, wherein, in General Formula 4, R³¹, R³², R³³, and R³⁴ are each independently a C1-C30 linear alkyl group, a C1-C30 branched alkyl group, a C3-C30 cycloalkyl group, a C6-C30 aryl group, or a C7-C30 alkylaryl group.

18. The method of claim 11, wherein, in General Formula 2, M is Si and the second repeating unit is represented by General Formula 2A: 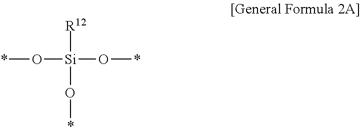
wherein, in General Formula 2A, R¹² is a C1-C30 linear alkyl group, a C1-C30 branched alkyl group, a C3-C30 cycloalkyl group, a C6-C30 aryl group, or a C7-C30 alkylaryl group.

19. The method of claim 11, wherein,
in General Formula 2, M is Si, and,
in the organometallic oxide cluster, a molar ratio of Sn is equal to or greater than a molar ratio of Si.

20. The method of claim 11, wherein,
in the exposing of the first region of the photoresist film to light, the first region is exposed to light by using a KrF excimer laser (248 nm), an ArF excimer laser (193 nm), an F₂ excimer laser (157 nm), or an extreme ultraviolet (EUV) laser (13.5 nm).
